(19) United States
(12) Patent Application Publication
(10) Pub. No.: US 2012/0129279 A1
(43) Pub. Date: May 24, 2012

(54) IMPRINTING METHOD, IMPRINTING APPARATUS AND MEDIUM

(76) Inventors: Yasuo MATSUOKA, Kanagawa (JP); Takumi OTA, Kanagawa (JP); Ryoichi INANAMI, Kanagawa (JP)

(21) Appl. No.: 13/230,197

(22) Filed: Sep. 12, 2011

(30) Foreign Application Priority Data
Nov. 22, 2010 (JP) 2010-260294

(51) Int. Cl. H01L 21/66; B05C 9/14; B05C 9/12; B05C 11/02; B05C 11/00

(52) U.S. Cl. 438/16; 118/100; 118/712; 118/620; 257/E21.53

(57) ABSTRACT

According to one embodiment, there is provided an imprinting method for applying a first hardening resin material on a substrate to be processed and transferring a pattern of a semiconductor integrated circuit formed on a template onto the substrate to be processed on which the first hardening resin material is applied, wherein a second hardening resin material with higher separability than the first hardening resin material is applied on at least part of the outer periphery of an area in which the pattern is formed by one transferring.

### CROSS-REFERENCE TO RELATED APPLICATIONS

This application is based upon and claims the benefit of priority from the prior Japanese Patent Application No. 2010-260294, filed on Nov. 22, 2010; the entire contents of which are incorporated herein by reference.

### FIELD

Embodiments described herein relate generally to an imprinting method, an imprinting apparatus and a medium.

### BACKGROUND

A nanoimprint lithography technique (which will be simply referred to as nanoimprinting below) is known as a semiconductor integrated circuit manufacturing technique. The nanoimprinting is a technique for pressing a template on which a pattern of a semiconductor integrated circuit is formed onto a resist applied to a semiconductor wafer, and thereby transferring a pattern formed on the template onto the resist.

### BRIEF DESCRIPTION OF THE DRAWINGS

FIGS. 1A to 1D are diagrams for explaining a transferring step by nanoimprinting;

FIG. 2 is a diagram for explaining a structure of an imprinting apparatus according to a first embodiment of the present invention;

FIG. 3 is a diagram illustrating exemplary application of two kinds of resist materials;

FIG. 4 is a diagram for explaining an exemplary structure of a controller;

FIG. 5 is a diagram for explaining exemplary dropping in a first drop recipe;

FIG. 6 is a diagram for explaining exemplary dropping in a second drop recipe;

FIG. 7 is a flowchart for explaining an imprinting method according to the first embodiment of the present invention;

FIG. 8 is a diagram for explaining an exemplary pattern group to be formed;

FIG. 9 is a diagram for explaining exemplary dropping in the second drop recipe;

FIG. 10 is a diagram for explaining an exemplary structure of a controller according to a second embodiment; and

FIG. 11 is a flowchart for explaining an imprinting method according to the second embodiment.

### DETAILED DESCRIPTION

In general, according to one embodiment, there is provided an imprinting method for applying a first hardening resin material on a substrate to be processed and transferring a pattern of a semiconductor integrated circuit formed on a template onto the substrate to be processed on which the first hardening resin material is applied, wherein a second hardening resin material with higher separability than the first hardening resin material is applied on at least part of the outer periphery of an area in which the pattern is formed by one transferring.

Exemplary embodiments of an imprinting method, an imprinting apparatus and a medium will be explained below in detail with reference to the accompanying drawings. The present invention is not limited to the following embodiments.

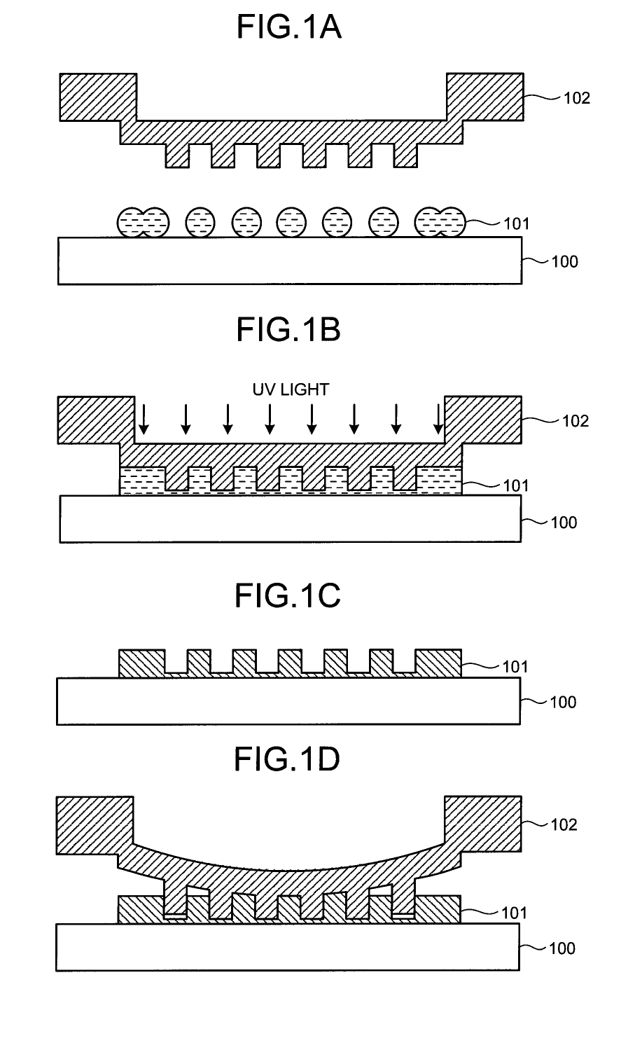

A typical transferring step by nanoimprinting will be described. FIGS. 1A to 1D are diagrams for explaining the transferring step by nanoimprinting. Optical nanoimprinting for hardening a resist (optical hardening resin material) by ultraviolet light irradiation will be described herein by way of example, but the present embodiments are applicable to thermal nanoimprinting for hardening a resist (thermal hardening resin material) by heating.

In the transferring step, as illustrated in FIG. 1A, a resist material 101 (exemplary hardening resin material) is first applied on a wafer 100 to be processed (exemplary substrate to be processed). The imprinting apparatus has a nozzle that is two-dimensionally driven in parallel to the wafer 100 and is directed for discharging the resist material 101, and can locally change the application amount of the resist material 101 based on a drop recipe defining an application amount distribution of the resist material. The drop recipe is created based on design data (pattern data) of a design pattern (or a resist pattern or template pattern may be also possible). The drop recipe is defined such that the application amount is large at a resist pattern with high density and the application amount is small at a resist pattern with low density. In FIG. 1A, with the imprinting apparatus of this type, droplets of the resist material 101 drop on concave parts of a template 102.

Subsequently, the template 102 is pressed onto the wafer 100 on which the resist material 101 is applied. The resist material 101 enters the concave parts of a template pattern formed on the template 102 due to a capillary action. After the resist material 101 fully enters the template pattern, an ultraviolet light is irradiated from above the template 102 as illustrated in FIG. 1B. The template 102 is made of a material such as quartz capable of transmitting an ultraviolet light (UV light), and the UV light irradiated from above the template 102 transmits the template 102 to be irradiated on the resist material 101. The resist material 101 is hardened by the UV light irradiation.

After the resist material 101 is hardened, the template 102 is separated therefrom, and the resist pattern is formed by the hardened resist material 101 on the wafer 100 as illustrated in FIG. 1C. The template 102 adheres to the hardened resist material 101 with a strong force. Thus, in the separation of the template 102, when a tension stress is applied between the template 102 and the resist material 101 with the bond surface therebetween as operational surface, the resist material 101 pulled by the template 102 elastically deforms depending on the tension stress. When the tension stress exceeds the adhesion force, the template 102 is released from the resist material 101 at once. At this time, the pattern by the resist material 101 can be damaged due to an impact caused by the release of the template 102, causing a defect. The template 102 may be damaged due to an impact caused by the separation.

The first embodiment of the present invention is such that for the resist pattern formed by one-shot, a resist material (second hardening resin material) having higher separability than the resist material (first hardening resin material) used for other sites is applied on at least part of the outer periphery so that the entire surface is separated at different timings depending on a site instead of being separated at once. The resist material having higher separability is applied to the outer periphery because the template is typically configured such that the outside the part in which the pattern is formed is held by a template holding mechanism and thus a stress on the template can be reduced during the separation when the template is separated from the periphery. For example, when the resist material with high separability is used for the entire outer periphery of the template 102, the template is separated from the outer periphery toward the inside due to the bent template at different timings as illustrated in FIG. 1D.

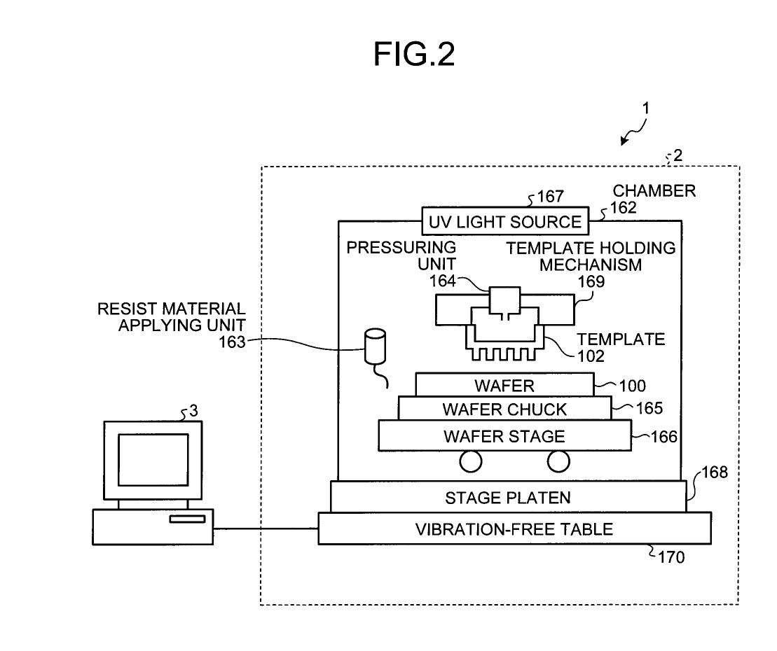

FIG. 2 is a diagram for explaining a structure of the imprinting apparatus according to the first embodiment of the present invention. As illustrated, the imprinting apparatus 1 includes an imprinting unit 2, and a controller 3 for controlling the imprinting unit 2.

In the imprinting unit 2, a wafer chuck 165 for holding the wafer 100, a movable wafer stage 166 for placing the wafer chuck 165 thereon, the template 102, a template holding mechanism 169, a resist material applying unit 163, a pressuring device 164, an UV light source 167 and the like are arranged in the same chamber 162. The chamber 162 is supported by a stage platen 168 and a vibration-free table 170.

The wafer 100 is placed on the wafer chuck 165 in the chamber 162. The template holding mechanism 169 holds the template 102. A sealed space is provided between the template holding mechanism 169 and the template 102, and the pressuring device 164 pressures the space thereby to make the center of the template 102 expanded during the pressing, as viewed from the wafer 100 held immediately below the template 102. The wafer stage 166 moves the wafer 100 downward the resist material applying unit 163. The resist material applying unit 163 applies the resist material on the wafer 100 in an inkjet system. Since the imprinting mechanism of the imprinting unit 2 is a step-and-repeat system, that is, a system for moving the wafer 100 by one-shot imprinting, the resist material applying unit 163 applies one-shot of resist material.

The resist material applying unit 163 includes a mechanism for dropping two kinds of resist materials. One kind of resist material is a first resist material (first hardening resin material) whose composition is adjusted such that the number of defects in one-shot is as small as possible, and the other kind of resist material is a second resist material (second hardening resin material) having higher separability than the first resist material. The features of the resist material, which influence the number of defects, include contraction rate, elastic force, base material adhesion force, charging property, solvent resistance, fluorine content rate, and the like. The features have a relationship in which any one feature is enhanced while other features deteriorate, and the most desirable composition for all the features is impossible. Thus, for example, the composition of the first resist material is changed and a template to be imprinted is used to perform the imprinting so that the best composition is selected. A composition having a higher contraction rate than the first resist material is selected as the composition of the second resist material.

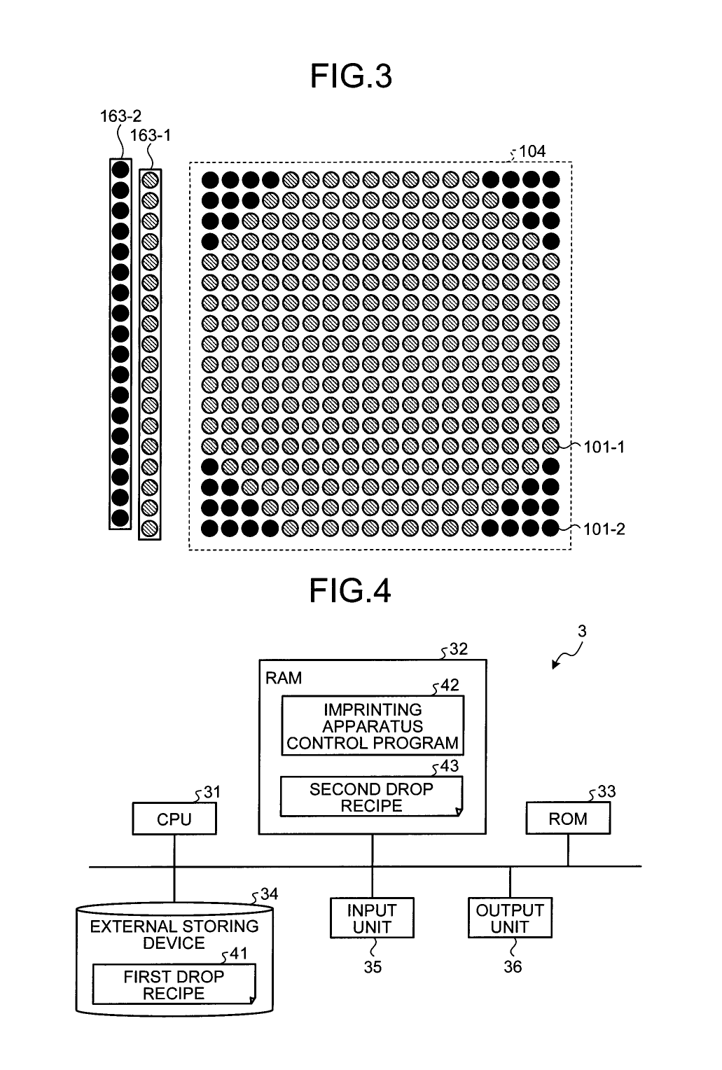

Specifically, the resist material applying unit 163 includes a nozzle for dropping the first resist material and a nozzle for dropping the second resist material. FIG. 3 is a diagram illustrating exemplary application of the two kinds of resist materials by the resist material applying unit 163. As illustrated in FIG. 3, the resist material applying unit 163 includes a nozzle 163-1 for applying the first resist material and a nozzle 163-2 for applying the second resist material. The first resist material 101-1 is applied by the nozzle 163-1 and the second resist material 101-2 is applied by the nozzle 163-2 on an one-shot drop area 104 on the wafer 100. The second resist material 101-2 is applied on the four corners of the one-shot drop area 104 and the first resist material 101-1 is applied on other parts in the drop area 104. The resist material applying unit 163 may be configured such that a nozzle is shared both for the first resist material and for the second resist material and the resist materials to be supplied to the nozzle are changeable thereby to apply the two kinds of resist materials.

After the resist materials are applied, the template holding mechanism 169 presses the template 102 onto the resist material from immediately above the part of the wafer 100 on which the resist materials are applied, and the UV light source 167 irradiates an UV light onto the resist materials via the template 102. After the resist materials are hardened, the template holding mechanism 169 pulls the template 102 immediately above so that the template 102 is separated from the resist materials.

The controller 3 creates a drop recipe for using the first and second resist materials from the drop recipe created for using only the first resist material.

FIG. 4 is a diagram for explaining an exemplary structure of the controller 3. As illustrated, the controller 3 is configured similar to a typical computer to include a CPU 31, a RAM (Random Access Memory) 32, a ROM (Read Only Memory) 33, an external storing device 34, an input unit 35 and an output unit 36. The CPU 31, the RAM 32, the ROM 33, the external storing device 34, the input unit 35 and the output unit 36 are interconnected via a bus line.

The CPU 31 executes an imprinting apparatus control program 42 as a computer program for controlling the imprinting unit 2. The input unit 35 includes a mouse and a keyboard, and is input the operations of the imprinting apparatus 1 by an operator. The operation information input into the input unit 35 is sent to the CPU 31.

The external storing device 34 includes a hard disk drive, for example, and stores a drop recipe (first drop recipe 41) in which the resist material applying unit 163 in the imprinting unit 2 applies the resist material. The first drop recipe 41 is created for using only the first resist material, and is created in a typical method. For example, a distribution of pattern densities is obtained from the design data, and the drop positions and the drop amounts are calculated depending on the obtained densities to create the first drop recipe 41.

The imprinting apparatus control program 42 is stored in the ROM 33 or the external storing device 34 and is loaded to the RAM 32 via the bus line. The CPU 31 executes the imprinting apparatus control program 42 loaded in the RAM 32. The CPU 31 executes the imprinting apparatus control program 42 developed in the RAM 32 to read the first drop recipe 41 stored in the external storing device 34 and thereby to create the second drop recipe 43 for using the two resist materials. In other words, the second drop recipe defines therein which to use the first resist material or the second resist material per drop position of a droplet.

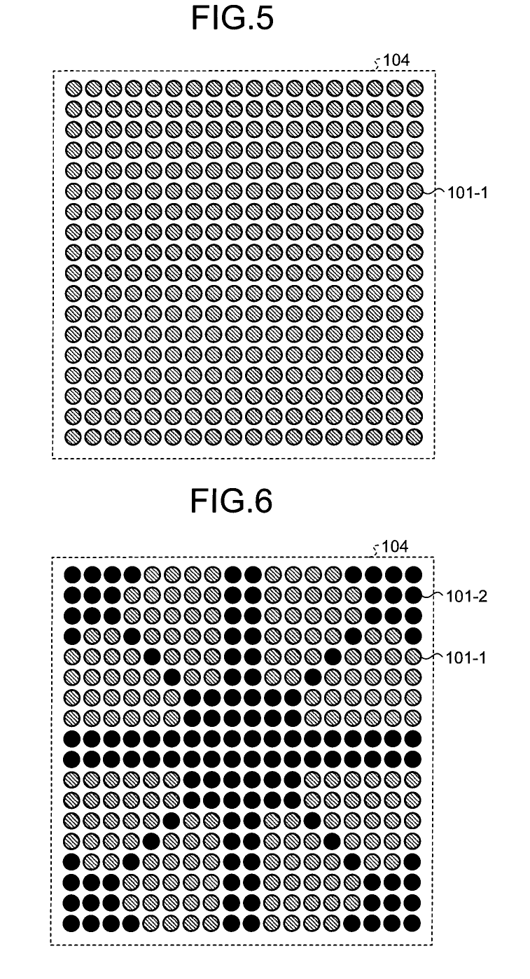

FIG. 5 is a diagram for explaining exemplary dropping in the first drop recipe 41. As illustrated, in the first drop recipe 41, only the first resist material 101-1 is used to apply the resist material on the one-shot drop area 104. In the second drop recipe 43, the first resist material 101-1 and the second resist material 101-2 are used to apply the resist materials as illustrated in FIG. 3. In the first embodiment of the present invention, the second drop recipe 43 may be set such that the second resist material is dropped on at least part of the outer periphery of the one-shot drop area. For example, as illustrated in FIG. 6, the second resist material 101-2 may be dropped not only at the four corners of the drop area 104 but also inside as desired.

The generated second drop recipe 43 is placed in the RAM 32, for example. The CPU 31 uses the second drop recipe 43 to drive and control the resist material applying unit 163, thereby applying the two kinds of resist materials on the wafer 100.

The output unit 36 is a display device such as liquid crystal monitor, and displays output information such as operation screen for the operator based on the instructions from the CPU 31.

The imprinting apparatus control program 42 executed by the controller 3 may be stored on a computer connected to a network such as The Internet and downloaded via the network to be provided or distributed. The imprinting apparatus control program 42 may be provided or distributed via the network such as The Internet. The imprinting apparatus control program 42 may be previously incorporated in the ROM 33 or the external storing device 34 to be provided to the controller 3. The imprinting apparatus control program 42 may be recorded in a recording medium such as CD-ROM to be provided or distributed.

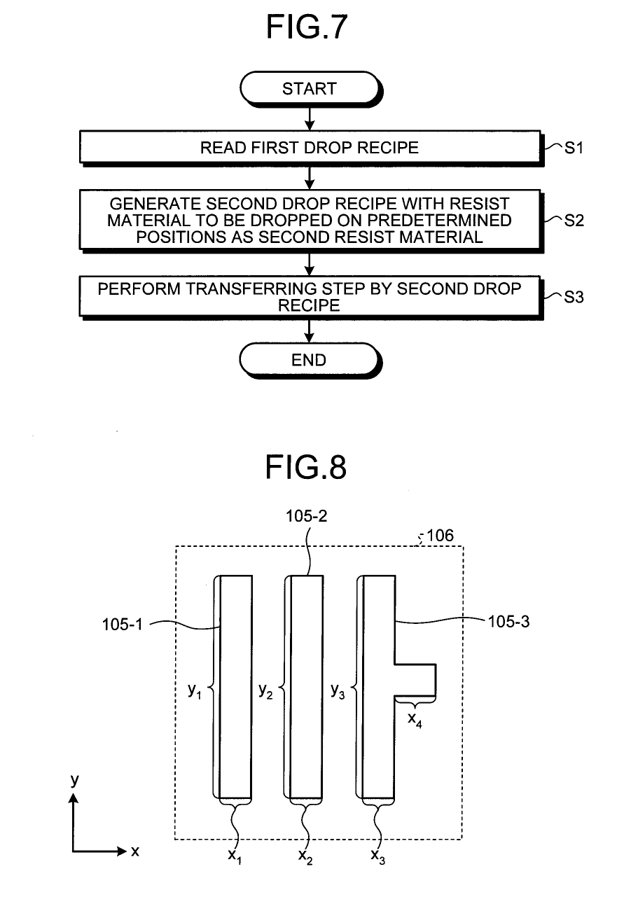

FIG. 7 is a flowchart for explaining the imprinting method executed by use of the imprinting apparatus 1 according to the first embodiment of the present invention. As illustrated, the CPU 31 first reads the first drop recipe 41 from the external storing device 34 (step S1). Then, the CPU 31 generates the second drop recipe 43 by using the resist material to be dropped on predetermined positions in the read first drop recipe 41 as the second resist material (step S2). The CPU 31 uses the generated second drop recipe 43 to perform the transferring step (step S3) and the operation ends.

In this way, according to the first embodiment of the present invention, since there is configured such that the second resist material with high separability is applied on at least part of the outer periphery of the drop area 104 on which the pattern is formed by one transferring, the template is separated from the part of the outer periphery of the drop area 104 on which the second resist material is applied, thereby preventing the entire surface from being separated at once, and thus an impact on the template and the resist pattern can be reduced during the separation as much as possible.

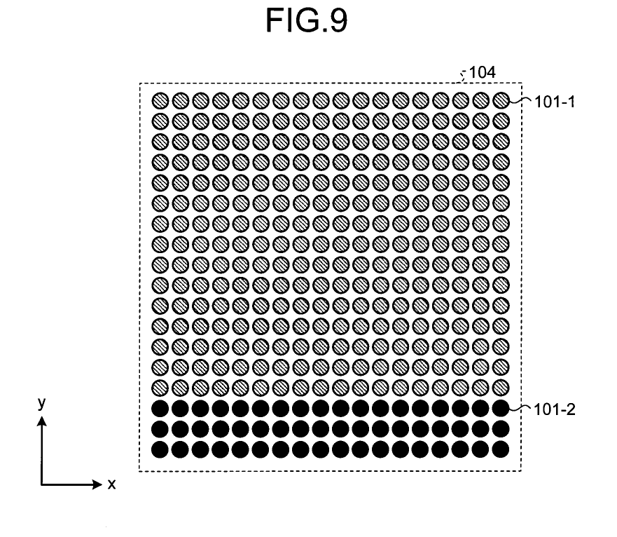

When a pattern group in which strongly-anisotropic patterns are deflected and arranged in one direction is formed like a line and space, the separation is performed in a direction in which the line extends (that is, in the deflection direction), the number of defects can be reduced as compared with the separation in a direction orthogonal to the deflection direction. For example, line-shape patterns 105-1, 105-2 extending in a y-axis direction, and a line-shape pattern 105-3 orthogonally connected to a short line are formed in an area 106 on the wafer illustrated in FIG. 8. The deflection direction of the pattern group is assumed as the y-direction. With the pattern group, the separation is gradually performed in the y-axis direction thereby to reduce the number of defects. For that, the second resist material 101-2 may be dropped at the bottom of the drop area 104 in parallel to an x-axis direction as illustrated in FIG. 9, for example. According to a second embodiment, for the pattern group in which the strongly-anisotropic patterns are deflected and arranged, the drop positions of the second resist material are determined for reducing as many defects as possible.

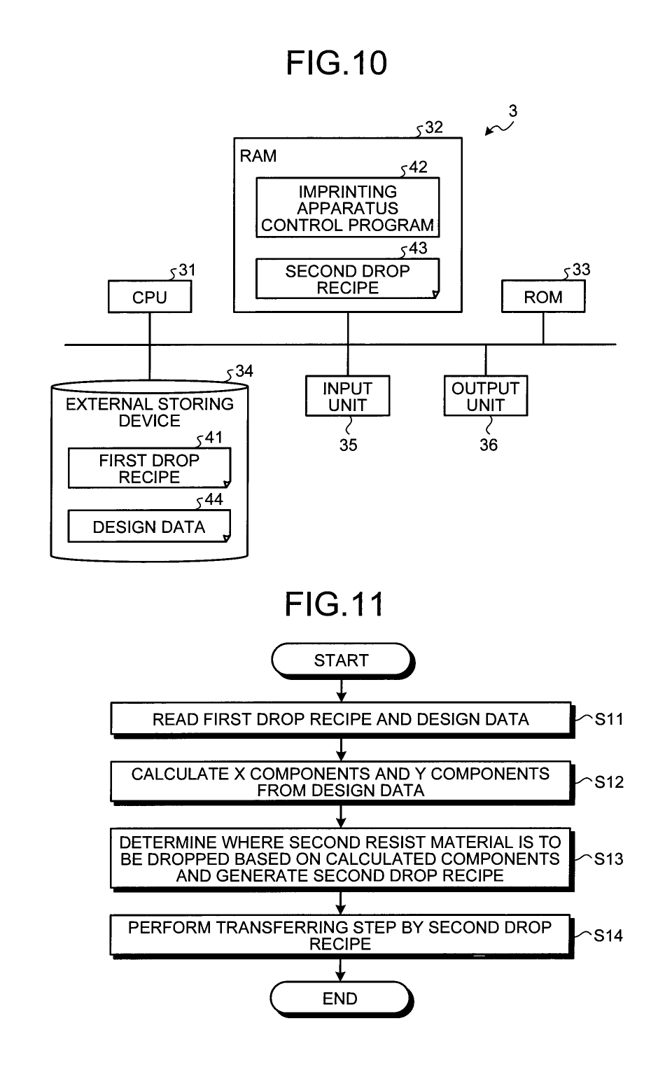

FIG. 10 is a diagram for explaining an exemplary structure of a controller according to the second embodiment. As illustrated, the controller 3 according to the second embodiment is different from the first embodiment in that design data 44 in addition to the first drop recipe is previously stored in the external storing device 34.

FIG. 11 is a flowchart for explaining an imprinting method according to the second embodiment. As illustrated, the CPU 31 first reads the first drop recipe 41 and the design data from the external storing device 34 (step S11). The CPU 31 calculates the X components and the Y components of the patterns from the read design data. For example, in the case of the pattern group illustrated in FIG. 8, the X components are (x1+x2+x3+x4) and the Y components are (y1+y2+y3). In the case of the line and space in which the lines are parallel to the y-axis as illustrated in FIG. 8, the Y components have a much larger value than the X components.

Subsequently, assuming that the axial direction having the larger calculated components is the deflection direction at the outer periphery of the drop area 104, the CPU 31 determines the area contacting the side perpendicular to the deflection direction as the area on which the second resist material is to be dropped, and thereby generates the second drop recipe 43 (step S13). For example, for the pattern group of FIG. 8, since the components of the Y-axis are larger than the components of the X-axis, the y direction is the deflection direction. Consequently, as illustrated in FIG. 9, the area on which the second resist material 101-2 is to be dropped is determined. FIG. 9 illustrates that the second resist material 101-2 is dropped only on the area contacting the lower side on the sheet in the periphery of the drop area 104, but the second resist material may be dropped on the area contacting the upper side on the sheet. The second resist material may be dropped on both the upper and lower parts on the sheet.

After step S13, the CPU 31 performs the transferring step based on the generated second drop recipe 43 (step S14), and the operation ends.

In this way, according to the second embodiment of the present invention, since there is configured such that the deflection direction of the pattern group formed by one transferring is obtained (step S12) and the area contacting the side perpendicular to the deflection direction in the outer periphery of the drop area 104 is determined as the area on which the second resist material is to be applied (step S13), for the pattern group in which strongly-anisotropic patterns to be transferred are deflected and arranged in one direction like the line and space, the number of defects occurring in the formed resist pattern can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An imprinting method for applying a first hardening resin material on a substrate to be processed and transferring a pattern of a semiconductor integrated circuit formed on a template onto the substrate to be processed on which the first hardening resin material is applied,
wherein a second hardening resin material with higher separability than the first hardening resin material is applied on at least part of the outer periphery of an area in which the pattern is formed by one transferring.

2. The imprinting method according to claim 1, further comprising:
obtaining a deflection direction of a pattern group formed by one transferring; and
determining an area contacting a side perpendicular to the obtained deflection direction in the outer periphery as an area on which the second hardening resin material is to be applied.

3. The imprinting method according to claim 2, wherein when obtaining the deflection direction, the total of X components and the total of Y components of patterns contained in the pattern group formed by the one transferring are obtained and a direction having the larger total is assumed as the deflection direction.

4. The imprinting method according to claim 1, wherein the first and second hardening resin materials are hardened by an ultraviolet light or heating.

5. An imprinting apparatus for applying a first hardening resin material on a substrate to be processed and transferring a pattern of a semiconductor integrated circuit formed on a template onto the substrate to be processed on which the first hardening resin material is applied,
wherein a second hardening resin material with higher separability than the first hardening resin material is applied on at least part of the outer periphery of an area in which the pattern is formed by one transferring.

6. The imprinting apparatus according to claim 5, further comprising a controller for obtaining a deflection direction of a pattern group formed by one transferring, and determining an area contacting a side perpendicular to the obtained deflection direction in the outer periphery as an area in which the second hardening resin material is to be applied.

7. The imprinting apparatus according to claim 6, wherein the controller obtains the total of X components and the total of Y components of patterns contained in the pattern group formed by the one transferring and a direction having the larger total is assumed as the deflection direction.

8. The imprinting apparatus according to claim 5, wherein the first and second hardening resin materials are hardened by a ultraviolet light or heating.

9. A non-transitory computer readable medium comprising instructions that cause a computer to:
receive an input of a first drop recipe for applying a first hardening resin material on a substrate to be processed for transferring a pattern of a semiconductor integrated circuit formed on a template; and
modify the first drop recipe such that a second hardening resin material with higher separability than the first hardening resin material is applied on at least part of the outer periphery of an area in which the pattern is formed by one transferring.

10. The medium according to claim 9, wherein the instructions causes the computer to:
obtain a deflection direction of a pattern group formed by one transferring; and
determining an area contacting a side perpendicular to the obtained deflection direction in the outer periphery as an area in which the second hardening resin material is to be applied.

11. The medium according to claim 10, wherein the instructions causes the computer to:
obtain the total of X components and the total of Y components of patterns contained in the pattern group formed by the one transferring when obtaining the deflection direction, and to assume a direction having the larger total as the deflection direction.

12. The medium according to claim 9, wherein the first and second hardening resin materials are hardened by an ultraviolet light or heating.
